(19) United States
(12) Patent Application Publication
(10) Pub. No.: US 2006/0158208 A1
(43) Pub. Date: Jul. 20, 2006

(54) Prober tester

(75) Inventors: Fayez E. Abboud, Pleasanton, CA (US); Paul Bocian, Saratoga, CA (US); Bassam Shamoun, Fremont, CA (US); Janusz Jozwiak, San Ramon, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/036,754

(22) Filed: Jan. 14, 2005

(51) Int. Cl. G01R 31/02

(52) U.S. Cl. 324/761

(57) ABSTRACT

A continuity test system adapted for testing individual contact pins within a flat panel test system is disclosed. The method and apparatus is designed to test continuity of individual contact pins via connection of a contact test pad assembly to a plurality of pins within a user defined pin arrangement. The contact test pad assembly has a plurality of contact points mounted thereon adapted to be in communication with individual contact pins within the defined pin arrangement. The system uses a test circuit in communication with the contact test pad assembly that is in communication with a power source and a controller that receives continuity information from the circuit and provides results to a user.

### BACKGROUND OF THE INVENTION

1. Field of the Invention

Embodiments of the invention generally relate to a test system for testing electronic devices on flat panel substrates. More specifically, to a method and apparatus for determining proper operability of the test system.

2. Description of the Related Art

Active matrix liquid crystal displays (LCDs) are commonly used for applications such as computer and television monitors, cell phone displays, personal digital assistants (PDAs), and an increasing number of other devices. Generally, an active matrix LCD comprises two glass plates having a layer of liquid crystal materials sandwiched therebetween. One of the glass plates typically includes a conductive film disposed thereon. The other glass plate typically includes an array of thin film transistors (TFTs) coupled to an electrical power source. Power is applied to each TFT to generate an electrical field between a TFT and the conductive film. The electrical field changes the orientation of the liquid crystal material, creating a pattern on the LCD.

In order to provide quality control for thin film transistors on a large area glass substrate, it is desirable to conduct a liquid crystal display or pixel array test which allows a TFT LCD manufacturer to monitor and correct defects in the pixels during processing. One known method of testing pixels is known as electron beam testing (EBT) where each pixel electrode on a substrate is sequentially positioned under an electron beam. One such device is an electron beam array test system available from AKT, Inc., a subsidiary of Applied Materials, Inc. located in Santa Clara, Calif.

In order for the LCD array test to be conducted, a prober is used. A typical prober consists of a frame that places a substrate with a flat panel display or multiple displays under investigation in electrical communication with a power source. The perimeter of the display (or multiple displays) on the substrate has a plurality of contact pads that are in electrical communication with individual TFT's and corresponding pixel electrodes. The frame has a plurality of electrical contact pins at locations which correspond to the contact pads of the substrate.

In operation, the substrate contacts the prober and the contact pads of the display or displays are placed into contact with the electrical pins of the prober. The contact pads, in turn, are in electrical communication with a pre-defined set of the thin film transistors, or pixels. An electrical current is delivered through the pins to the contact pads. The current travels to and electrically excites the corresponding pixels. An electron beam is directed at the pixel and secondary electrons emitted from the pixels are sensed with a detector in order to confirm operability of the pixels. The operability of the individual pixels by the electron beam is typically conducted on a simple “pass” “no-pass” basis whereby the display may be repaired and could be scrapped if a predetermined number or percentage of pixels are judged inoperable or “no-pass”.

A problem using this type of testing system has been encountered in the past and has been isolated to the electrical continuity of prober pins. The electrical current supplied to the pin and used to energize the TFT's will not be translated to the contact pad on the substrate, and ultimately, the individual pixel or LCD array being tested. This results in a pixel that is not. electrically excited and may induce “no-pass” detection by the electron beam method since there is no electrical current supplied to it. This “no-pass” indication may be false if the pixel or LCD array is properly operable but for the application of the electrical current.

Another problem deals with the proper alignment of prober pins on the prober bars. In order for the pins to energize the contact pads on the substrate, the pins should be substantially perpendicular to the prober bar and in a spaced apart relation to each other. The prober pins, disposed on the bars, are typically not protected from accidental contact with parts of the machine when handling. If the prober frame is mishandled, the orientation of the prober pins may be disturbed and cause one or more adjacent pins to come into contact with each other. This contact will translate into a “short” in the circuit and will affect the current supplied to one or more contact pads on the substrate, thereby rendering a pixel or LCD array inoperable.

In the past, performing tests of the electrical continuity of individual prober pins, if performed at all, has been time consuming and expensive. The sheer number of prober pins mounted on a prober bar, with each pin having a respective fine wire path through cables and connectors, makes isolating the pin circuit very difficult. Also, the small size and number of prober pins makes inspection of the orientation of the pins very difficult. While performing these tests and checks are not impossible and may be performed manually, it requires significant man-hours that will translate into higher production costs of flat panel displays. On the other hand, if these tests are not performed, production costs are negatively impacted by needless repair or scrapping of displays that otherwise may be operable if one or more prober pins were properly operable and oriented correctly.

Due to these considerations for testing prober pins and assuring realistic pixel testing, there is a need in the art for a prober test system and apparatus that is capable of performing continuity checks on a plurality of individual prober pins that is simple, reliable and minimizes the number of man-hours required for performance. There is also a need for an apparatus that can sufficiently protect and maintain the orientation of a plurality of prober pins to minimize shorts in the prober test system.

### SUMMARY OF THE INVENTION

The invention generally provides an improved method and apparatus for testing prober pins with a test device. The novel test system will be adapted to mount on a prober bar or probe head disposed on a prober frame and enable testing of individual prober pins and their respective fine wire connections. The invention enables isolation of individual prober pins and, in one embodiment is an attachment of a printed circuit board that is adapted to provide contact points for a plurality of individual prober pins. The individual contact points are adapted to detect, receive and transmit an electrical current from an individual prober pin to a device that receives and records the test current, thereby providing continuity information.

In another embodiment, a prober pin test system is described via the attachment of a contact test pad assembly configured to detachably connect to a plurality of prober pins, a controller, and a prober pin test circuit in communication with the contact test pad assembly and the controller.

In another embodiment, a continuity test apparatus is described having a contact test pad assembly, configured to detachably connect to a prober pin arrangement, a controller, and a prober pin test circuit connected to the contact test pad, the prober pin test circuit comprising, a voltage divider, an input buffer, an open drain driver, a prober pin, a shift register, and a pull-up resistor.

In another embodiment a continuity test method is described having the steps of positioning a prober bar with a plurality of prober pins disposed thereon in communication with a contact test pad assembly, applying a first voltage to a first contact point on the contact test pad assembly, sensing a second voltage on a prober pin under test corresponding to the first contact point and determining whether or not there is continuity between the first contact point and the prober pin under test based on the second voltage.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a partial perspective view of an exemplary prober assembly adapted to test flat panel displays.

FIG. 2 is a bottom view of an exemplary prober bar from the prober assembly of FIG. 1.

FIG. 3 is a plan view of a prober frame layout positioned adjacent a plurality of flat panel displays.

FIG. 4A illustrates exemplary components and hardware of a prober pin test system.

FIG. 4B is a top view of an exemplary contact test pad assembly.

FIG. 4C is a view of the back of the contact test pad assembly.

FIG. 4D is an exemplary arrangement with the pin test assembly positioned to test prober pins.

FIG. 5A is a schematic diagram of an exemplary prober pin test circuit.

FIG. 5B is a schematic diagram of one example of operation of the prober pin test circuit.

FIG. 5C is a schematic diagram of another example of operation of the prober pin test circuit.

FIG. 5D is a schematic diagram of another example of operation of the prober pin test circuit.

FIG. 6 is a flow chart for an exemplary prober pin testing method.

FIG. 7 is an exemplary logic flow chart of the present invention.

FIG. 8 is a table depicting various input/output signals.

FIG. 9 is a table depicting various inputs, outputs, and results.

### DETAILED DESCRIPTION

The invention generally provides an apparatus and system for testing an individual prober pin within a plurality of prober pins disposed on a prober bar that is part of an electronic device test system. For purposes of this disclosure, the term “test system” means any system that may be used to test electronic devices on a substrate. Such a test system may include optical inspection systems, electron beam test systems, systems that detect color changes, and others.

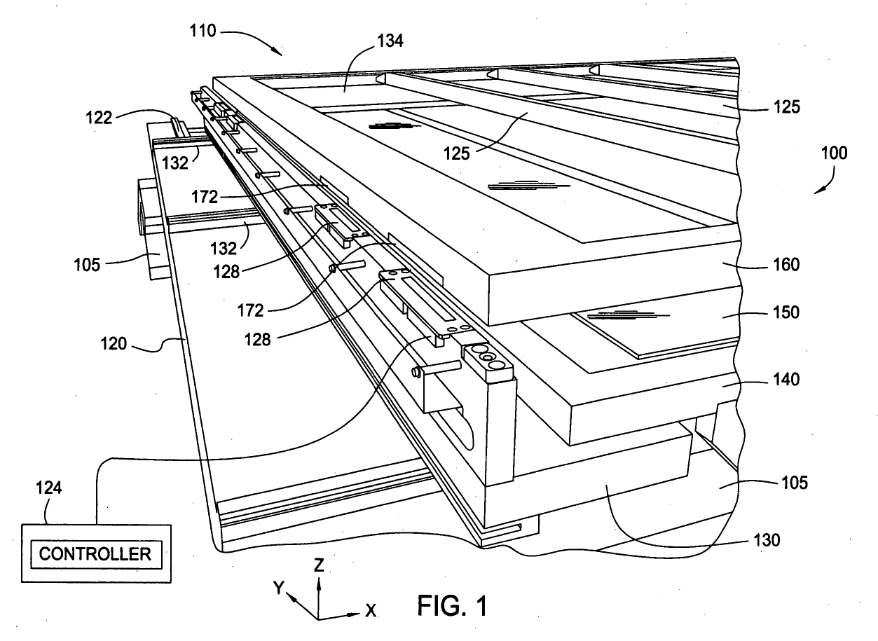

FIG. 1 is a partial perspective view of an exemplary prober assembly 110. The prober assembly 110 is part of an electronic device test system 100, depicted in this exemplary Figure as part of an electron beam test system, though other electronic test systems could benefit from the invention. The prober assembly 110 is positioned on a test system table 105 that typically moves the prober assembly 110 in at least “x”, “y” and “z”, directions. The table 105 supports various plates 120, 130, 140 that translate the prober apparatus 110 in “y”, “x”, and “z”, directions, respectively. The plate 140 is supported by “x” plate 130, which is supported by “y” plate 120, both horizontally moving (i.e., “x” and “y” movement) plates 120, 130 having various mechanical bearing surfaces 122 and 132. The “z” plate 140 supports a substrate 150 and is capable of movement in a vertical (“z”) direction that is adapted to place the substrate 150 into close proximity to the prober assembly 110. A detailed description of a prober assembly operation and components of a test system 100 can be found in the description of FIGS. 1-9 of U.S. patent application Ser. No. 10/903,216 entitled “Configurable Prober For TFT LCD Array Test”, filed Jul. 30, 2004, which is incorporated by reference herein.

As indicated, a substrate 150 is shown supported by plate 140 below the prober assembly 110. The illustrative substrate 150 is a large area glass, polymer, or other suitable substrate that has a plurality of conductive electronic devices formed thereon, such as a plurality of thin film transistors (TFT's).

Where the test system 100 is an electron beam test system, the system may include a prober transfer assembly, a transfer apparatus, a load lock chamber, a testing chamber and, optionally, a prober storage assembly. The testing chamber will have electron beam columns for directing electron beams down onto the pixels under inspection. Details of an exemplary electron beam test system containing such features are disclosed in the pending U.S. patent application Ser. No. 10/778,982 entitled “Electron Beam Test System with Integrated Substrate Transfer Module”, filed on Feb. 12, 2004, which is incorporated herein by reference.

The prober assembly 110 has a polygonal frame 160 having four sides (only three are seen in FIG. 1). The frame 160 defines the perimeter of the substrate 150 and includes one or more prober bars 125. In the view of FIG. 1, three separate prober bars 125 are shown within the frame 160 in a “y” axis; however, other numbers of prober bars and “x” axis prober bars may be employed either alone, or in combination with the “y” axis prober bars 125. The areas defined between the prober bars 125, and between the prober bars 125 and the frame 160, form test areas 134. The prober bars 125 have a plurality of contact pins disposed thereon adapted to contact the substrate 150 at specific locations. The prober assembly 110 may also be configurable, meaning that the prober bars 125 may be moved and positioned within the prober frame 160 to adapt to various contact pad configurations on the substrate 150 or multiple displays. The contact pins disposed on the prober bars 125 may also be configured to adapt to a user defined substrate 150 or flat panel display.

The prober frame 160 has a plurality of electrical connection blocks 172, which are adapted to place the prober frame 160 and its respective prober pins in electrical communication with a pixel test controller 124 via electrical mating blocks 128 mounted on the “x” plate 130 of the prober assembly 110. In FIG. 1, the prober frame 160 is shown lifted from the “x” plate 130, but in operation the prober frame 160 will be guided by locating pins on the “x” plate 130, thereby causing a proper mating between the connection blocks 172 and the mating blocks 128. The electrical connection blocks 172 and the mating blocks 128 are rows of terminals that are adapted to be in communication with each other via a suitable connector. The mating blocks are subsequently in communication with the pixel test controller 124 by a suitable cable during a test procedure.

As previously mentioned, the prober assembly 110 has a plurality of electrical contact pins mounted to the prober bars 125, referred to as prober pins 220. One type of prober pin 220 is a pogo pin. The prober pins 220 are adapted to snap-fit in place along each of the prober bars 125 of the prober frame 160 and are in electrical communication with the electrical connection blocks 172 via appropriate cables and connections. As will be explained in greater detail below, the prober pins 220 are positioned and oriented such that each of the prober pins 220 will make electrical contact with a corresponding contact point adjacent or disposed on a flat panel substrate.

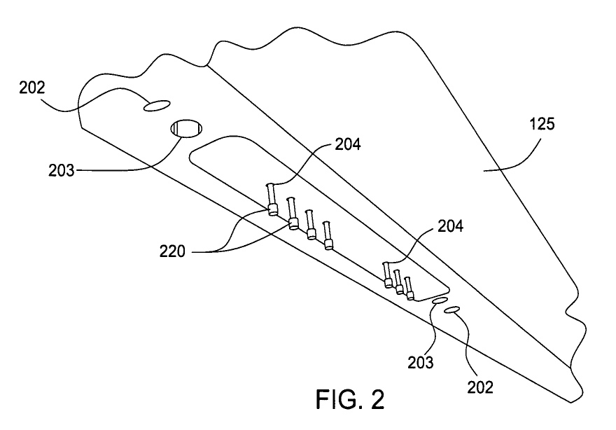

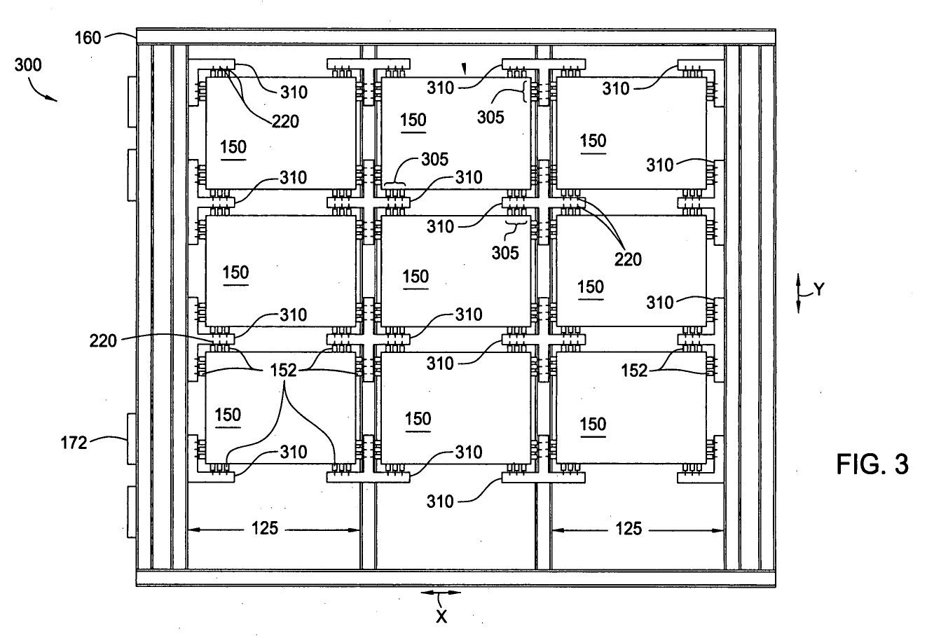

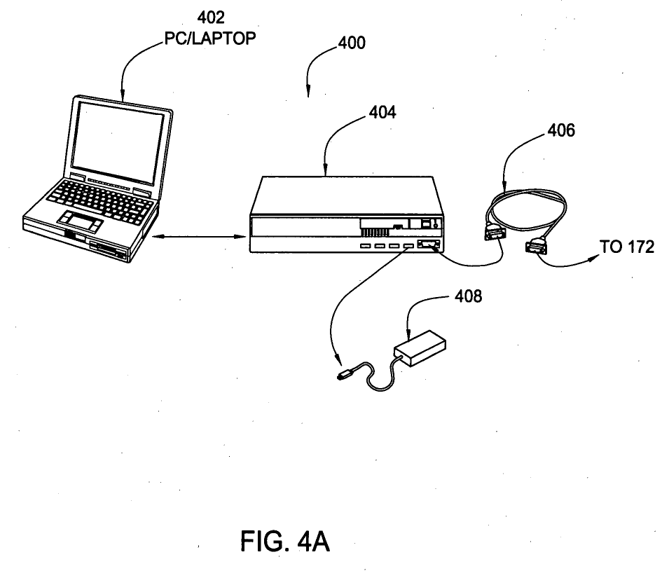

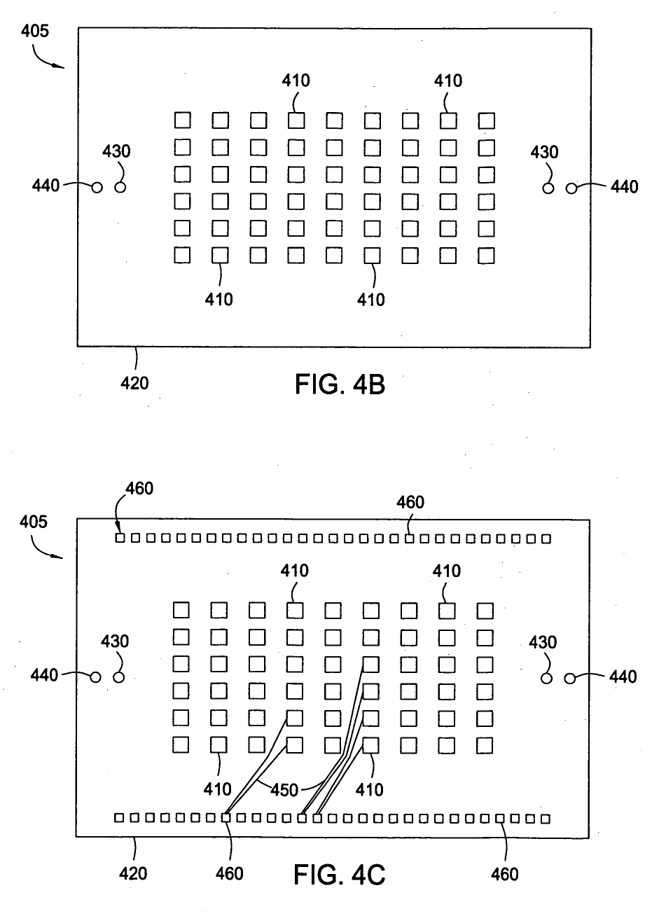

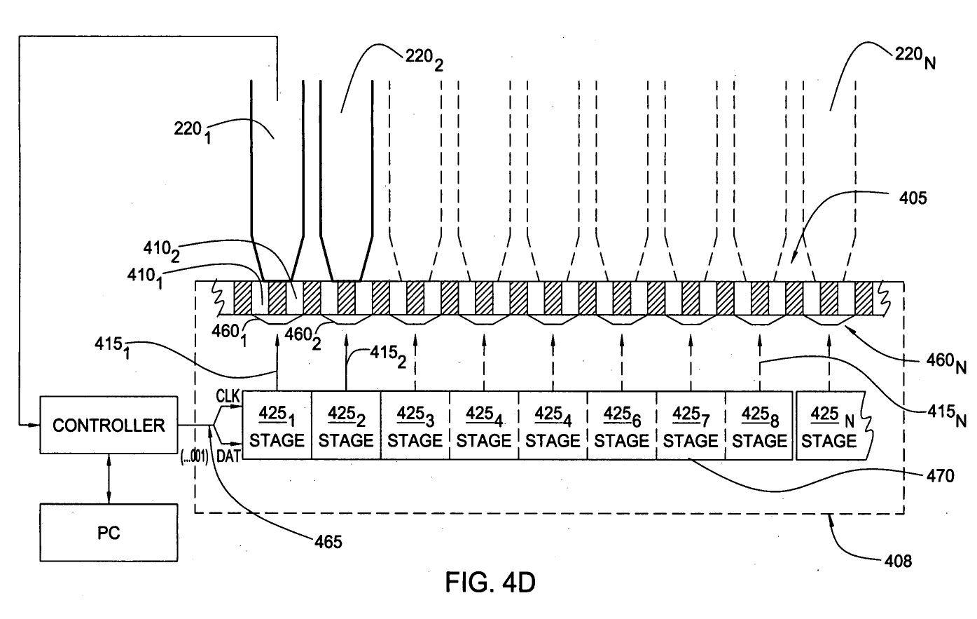

FIG. 2 presents a bottom view of an exemplary prober bar 125 similar to one of the prober bars 125 seen in FIG. 1. A lower side of the prober bar 125 has a plurality of electrical prober pins 220 that extend from the prober bar 125. The prober pins 220 may be selectively configured during the initial prober setup by press fitting the pins 220 into suitable holes 204 along the prober bars 125. At least two openings 203 adapted to receive alignment pins 430 (seen in FIGS. 4A and 4B) are adjacent to at least two threaded holes 202 that are adapted to receive a fastener such as a screw. The openings 203 and the threaded holes 202 are adapted to provide alignment and a fastening means for a contact test pad 400 that will be described in detail in reference to FIGS. 4A and 4B. Also, probe heads 310 containing a plurality of prober pins 220 that will be described in reference to FIG. 3, may be movably and detachably mounted to the prober bars 125 and may be tested in accordance with this invention.

As discussed above, the prober pins 220 are configured to place the controller 124 in electrical communication with selected pixels or TFT's (or other devices) formed on the substrate 150. The controller 124 controls application of a voltage to a selected pixel and/or monitor(s) each pixel for changes in attributes, such as voltage, during testing by the exemplary method of sequential contact with at least one electron beam from a suitable electron beam column (not shown) onto the pixel. The prober pins 220 may extend radially from the prober bars 125, or may extend below the bars 125. In the embodiment shown in FIG. 2, the pins extend downward. However, in the prober layout 300 illustrated in FIG. 3, the pins 220 are shown radially from the prober bars 125.

FIG. 3 is a plan view of a prober frame layout 300 showing a prober frame 160 similar to the prober frame 160 of FIG. 1. The prober frame 160 includes a plurality of prober bars 125 attached to the prober frame 160. The prober frame layout 300 also includes one or more “T” shaped, “+” shaped, or “L” shaped prober heads 310 mounted on the prober bars 125. The prober heads 310 and their respective plurality of prober pins 220 form a patterned prober pin arrangement 305 that is configured to match the location of the substrate contact pads 152, which are in electrical communication with TFT's on a substrate or panel 150.

FIG. 4A illustrates exemplary components and hardware of a prober pin test system 400 adapted to test continuity of individual prober pins 220 within a patterned prober pin arrangement 305. Shown is a prober pin test controller 404 connected to a personal computer/laptop (PC) 402. The PC 402 is a commercially available desktop or laptop with suitable software and is in communication with the prober tester controller 404 over a suitable port, such as, a serial or USB port. The prober pin test controller 404 interfaces between the prober frame 160 via connection of a connector cable 406, such as an 8×50 Pin cable connector, to the electrical connection blocks 172 on the prober frame 160. The test controller 404 functions to drive appropriate circuits, such as serial data, clock, and latch signals, and transfers results back to the PC 402. Also shown is a pin test assembly 408 that is adapted to mount adjacent a plurality of prober pins 220 or probe heads 310 disposed on a prober bar 125. The pin test assembly 408 is connected to the test controller 404 via appropriate cables and connections, and comprises active circuits that are adapted to test continuity of individual prober pins 220.

FIG. 4B is a top view of an exemplary contact test pad assembly 405 that is part of the pin test assembly 408 of FIG. 4A. The contact test pad assembly 405 has a plurality of contact points 410 that are configured to make electrical contact with a patterned arrangement of prober pins 305. The location and number of contact points 410 on the test pad assembly 405 are adapted to match the predetermined location of contact pads 152 on the substrate 150. In other words, the substrate 150 will have an arrangement of contact pads 152 patterned around the perimeter of the substrate 150 and the prober frame 160 will have a corresponding number and pattern of prober pins 220 mounted on the prober bars 125 that are adapted to mate and make electrical contact with the similarly patterned contact pads 152. The contact points 410 on the test pad assembly 405 may be similarly patterned as the contact pads 152 for the purpose of continuity testing.

The test pad assembly 405 of the pin test assembly 408 may be detachably connected to the prober bars 125 or probe heads 310 by a frame or housing 420 with appropriate fasteners such as screws. The frame 420 may have at least one alignment device 430 adjacent to at least one fastener hole 440 that is adapted to receive a fastener, such as a screw. The alignment device 430 may be a pin or dowel attached to the pad 400 that will be appropriately received by the opening 203 in a prober bar 125 or probe head 310. Alternatively, the alignment device may be a suitable bore in the test pad assembly 405 adapted to receive a pin or dowel mounted to a prober bar 125 or probe head 310. When appropriately joined by the alignment device 430, the contact points 410 of the test pad assembly 405 are assumed to be in contact with each respective prober pin 220 on the prober bar 125 or probe head 310, and the test pad may then be fastened. However, various factors may induce a misalignment between one or more of the plurality of prober pins 220. In order to reduce this possibility, the test pad assembly 405 may have more than one contact point 410 for each prober pin 220, for example, the exemplary test pad assembly 405 shown in FIG. 4B may be designed to test no more than 20 individual prober pins 220, denoting a contact point 410 to pin 220 ratio of 2:1. Alternatively, the test pad assembly 405 may have one contact point 410 per prober pin 220-a ratio of 1:1.

The test pad assembly 405 of the pin test assembly 408 may further be configured to have more contact points 410 than the number of prober pins 220 in a patterned prober pin arrangement 305 to be tested. For example, the contact pad assembly 405 may have 100 contact points 410, the 100 points adapted to test 50 prober pins 220 (i.e. 2:1 ratio) if there are 50 pins 220 in the patterned prober pin arrangement 305 available for testing. However, the patterned prober pin arrangement 305 on the prober bar 125 or probe head 310 may only have 20 pins 220 available for testing. In this case, the invention allows testing of the 20 pins 220, i.e., the testing is based on the number of prober pins 220 that are on the prober bar 125 or probe head 310, not on the number of contact points 410 on the contact test pad assembly 405. This will allow a contact test pad assembly 405 to be designed that will adapt to many patterned prober pin arrangements 305 that may have a ratio of points 410 to pins 220 that is greater than 2:1.

The contact test pad assembly 405 may be a commercially available printed circuit board (PCB), or custom built PCB per user specific prober frame 160 or flat panel contact pad 152 configurations. Alternatively, the prober frame 160 manufacturer may include test pads assemblies 405 that compliment the particular prober frame 160. In this case, the test pad assemblies 405 may be attached to the prober frame 160 as described above to protect the prober pins 220 from damage during shipping or handling.

FIG. 4C shows the back of the test pad assembly 405 having test pad terminals 460 on the backside of the PCB that are in electrical communication with the contact points 410 by appropriate electrical connections or traces 450. The terminals 460 may be adapted to couple with a suitable PCB terminal, such as a header connector with a complimentary number of male or female pins. As will be explained in greater detail below, the terminals 460 will be connected to a shift register that is part of the pin test assembly 408 by an appropriate cable, and the shift register connected to the prober pin test controller 404. The contact points 410 are made from or coated with an inert material that will resist oxide formation, such as, for example, Au, Pt, Ni, Ti, or some alloy thereof. The points 410 may also be made of copper that is plated with any of the above materials.

FIG. 4D illustrates an exemplary arrangement with a contact test pad assembly 405 that is part of the pin test assembly 408 positioned to test prober pins 220_{N} (220₁ and 220₂) that are similar to the prober pins 220 of FIG. 2. Shown is a contact test pad assembly 405 of FIGS. 4B and 4C having a plurality of contact test point pairs 410₁, 410₂ in communication with a plurality of pad terminals 460₁ and 460₂. Each prober pin 220_{N} may be tested, in sequence, by shifting a transistor to transistor logical “1” through one or more shift registers 470 in the pin test assembly 408. For example, to test a first prober pin 220₁, a logical “1” may be shifted to a corresponding first shift register stage 425₁, via clock (CLK) and data (DAT) signals generated by the prober pin test controller 404 and sent to the shift register 470.

As will be described in greater detail below, the logical “1” may be applied to an input of an open drain driver (ODD) in the stage 425₁, thereby connecting an output 415₁ of the stage 425₁ to ground. If there is continuity between the prober pin 220₁ and one or both of the contact test points 410₁, a path to ground via the switched ODD will result in a known continuity logic signal provided to the pin test controller 404 via a suitable output cable. Further, by observing the output signals for other prober pins 220_{N} (other than prober pin 220₁ under test), prober pins shorted to the pin 220₁, under test, may be detected. For example, by testing only one pin 220_{N} at a time, with logical “0”'s shifted into the other stages 425, only a continuity logic signal for the prober pin under test should be observed. Observation of a continuity logic signal from another prober pin 220 may be indicative of a short between that pin and the pin under test.

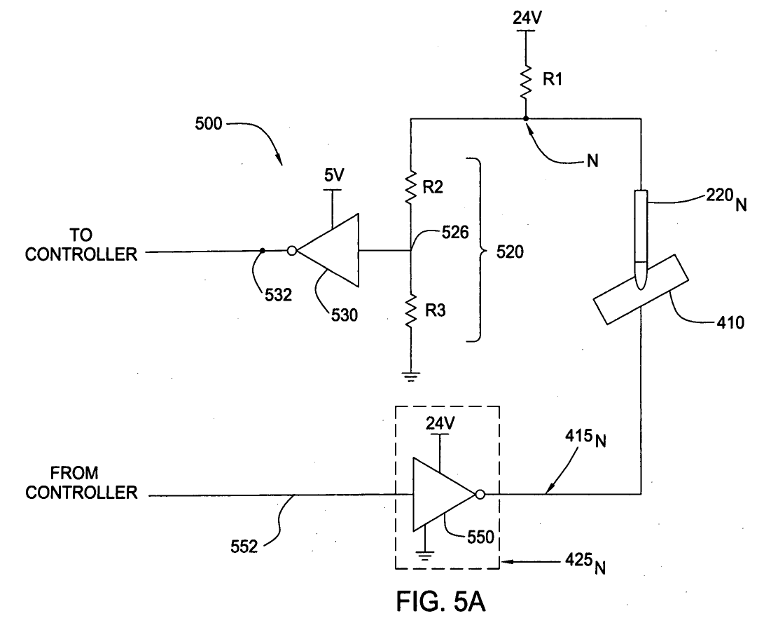

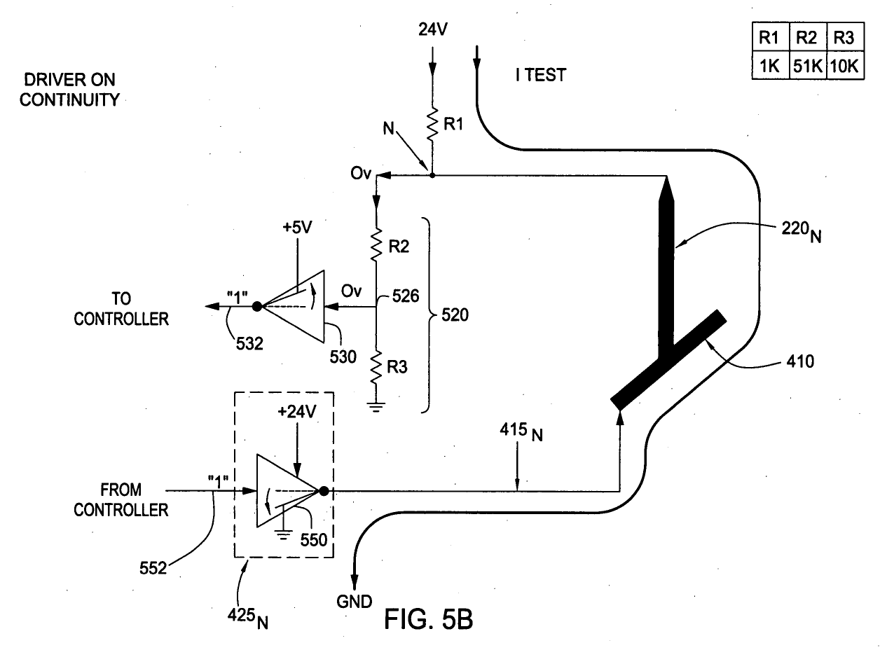

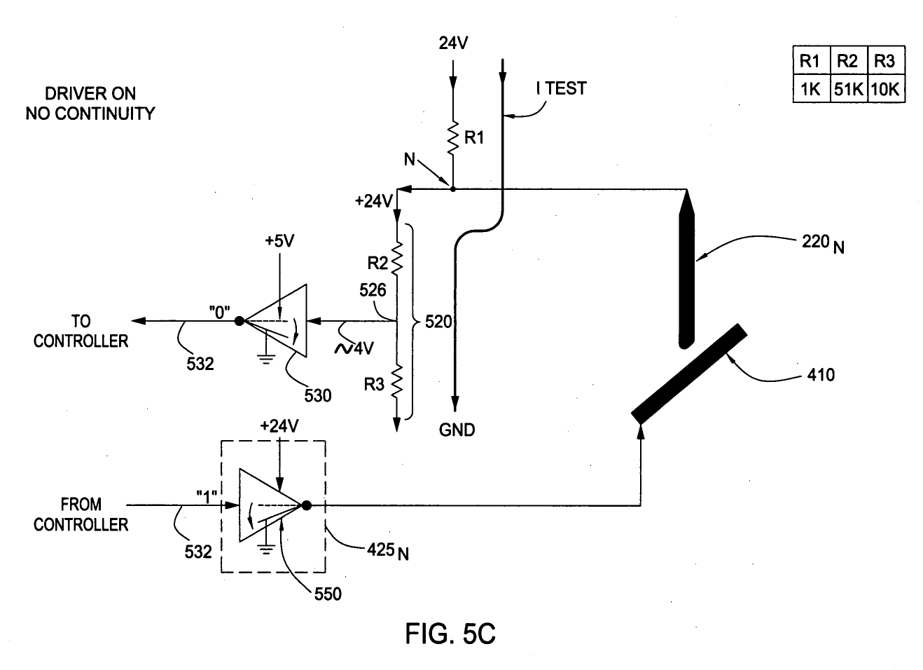

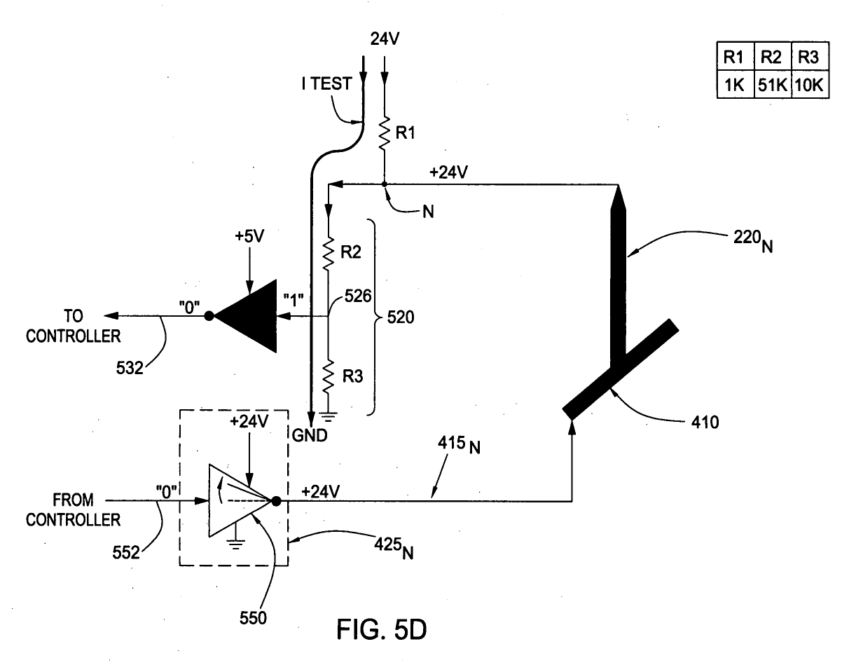

FIG. 5A depicts a schematic diagram of an exemplary prober pin test circuit 500 of the present invention adapted to isolate and test continuity of a single prober pin 220 disposed within a patterned prober pin arrangement 305 i.e., utilizing one stage 425_{N} similar to stage 425, seen in FIG. 4D. Shown in dashed lines are components of the prober pin test assembly 408 that comprises the stage 425_{N} having an ODD 550 adapted to receive an input 552 from the prober pin test controller 404, an output 415, and a contact point 410 similar to the contact test point pairs 410₁, 410₂ of FIG. 4D. The test circuit 500 further comprises a prober pin 220 in communication with a pull-up resistor R1 and a voltage divider 520 formed from resistors R2 and R3. An input buffer 530 is adapted to receive an input 526 from the voltage divider 520 and generates a logical output signal 532 (indicative of continuity) to the prober pin test controller 404. The resistor R1 and the ODD are connected to a power source that supplies a voltage that in this exemplary circuit is 24V. The voltage divider 520 generates the input 526 to the input buffer 530 by dividing a voltage at node N connected to the pull-up resistor R1. The input buffer 530 is illustratively an inverting input buffer and is in communication with a power source that supplies 5V in this exemplary circuit and generates a logical output 530 to the controller after inverting the signal from the input 526. The exemplary values of the resistors R1-R3 are: R1=1 Kohms; R2=51 Kohms, and R3=10 Kohms.

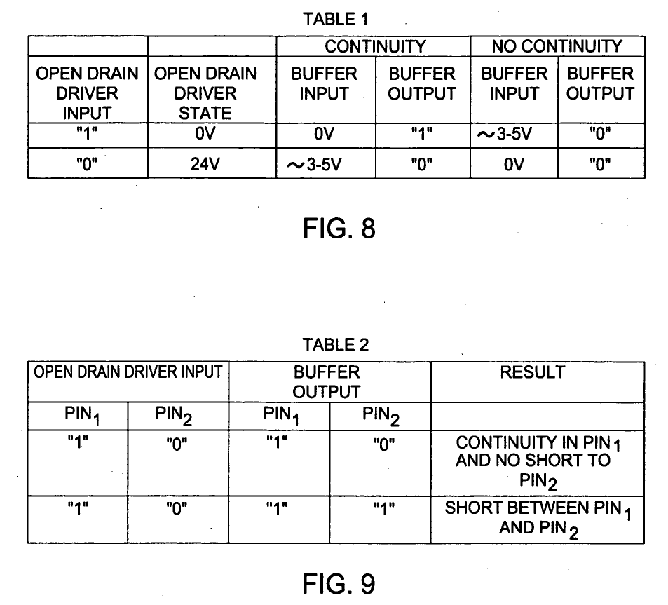

Operation of the prober pin test circuit 500 may be described with reference to FIGS. 5B-5D and Table 1 of FIG. 8. Referring first to FIG. 5B, testing a single prober pin 220 exhibiting sufficient continuity is shown. As illustrated, a logical “1” is applied to the input 552 of the ODD 550 (e.g., by shifting a logical “1” in, as previously described with reference to FIG. 4D). In response, because the ODD 550 is inverting, the output 415 of the ODD 550 will be switched to ground, as illustrated. In this example, there is continuity between the prober pin 220 and the contact test point 410 and the ODD 550 provides a path to ground for current ITEST from the 24V voltage source, thereby pulling node N and the input 526 of the input buffer 530 to a logical low level “0”. As a result, because the input buffer 530 is inverting, this logic “0” will result in the input buffer generating a logical “1” output signal 532, thereby indicating continuity between the prober pin 220 and the contact test point 410. This continuity indication allows a user to realize a functioning prober pin 220 that is ready to be put into operation pending testing of the other prober pins 220 on the prober frame 160.

On the other hand, if there is not continuity between the prober pin 220 and the contact test point 410 as illustrated in FIG. 5C, this discontinuity prevents the ODD 550 from providing a path to ground. Instead, the test current ITEST is directed through the voltage divider 520. Assuming R1=1 kohms, R2=51 kohms, and R3=10 kohms, a logical “1” (of approximately 4 v) will be applied to the input 526 of the input buffer 530, thereby resulting in a logical “0” output signal 532 indicating discontinuity between the prober pin 220 and the contact test point 410. This will alert a user to replace the malfunctioning prober pin 220 in order to repair the prober frame 160 for use in a test system.

Similarly, as illustrated in FIG. 5D, if the ODD 550 is turned off, via a logical “0” applied to its input 552, the test current ITEST is also directed through the voltage divider 520, again resulting in a logical “0” output signal. As previously described, this will enable a user to determine if there is a shorting pin. Assuming there is only one pin 220 under test at a time and the pin is not being tested at this time, a logical “1” detected at the output 532 of the input buffer 530 will alert a user to a shorting pin, as only the pin under test should exhibit a logical “1” output signal. The logic levels inputted and the respective known values are shown in Table 2 of FIG. 9.

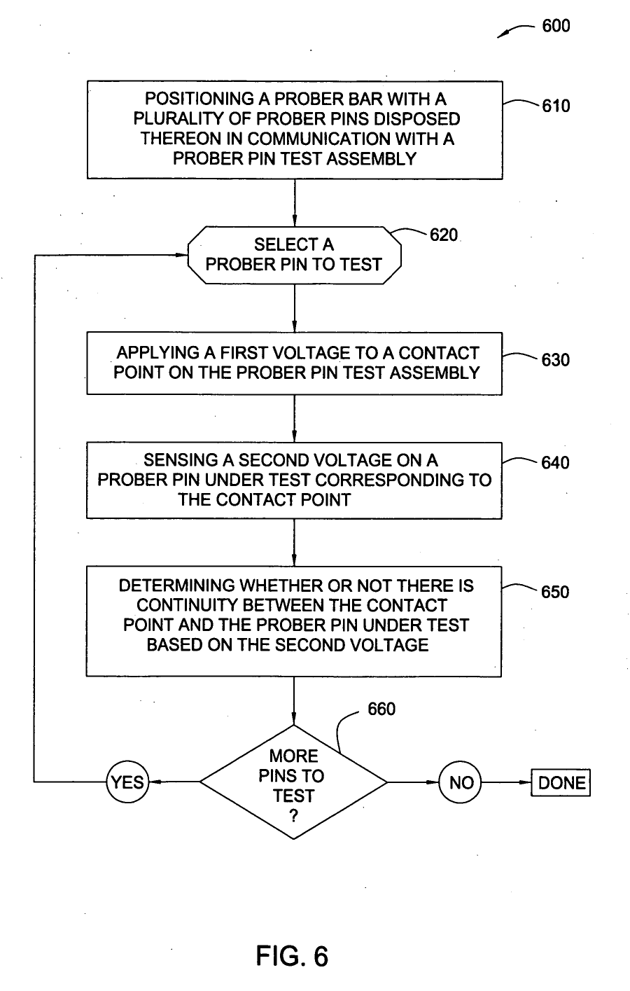

FIG. 6 is a flow diagram for an exemplary continuity test method 600. The method 600 starts at step 610 by positioning a prober bar 125 or probe head 310 with a plurality of prober pins 220_{N} disposed thereon in communication with a prober pin test assembly 408, the prober pin test assembly 408 having a plurality of contact test points 410_{N} that are in communication with the controller 404. The prober pin test assembly 408 is connected to the prober bar 125, the probe head 310, or the prober pins 220 disposed on a prober frame 160 in a patterned prober pin arrangement 305. Step 620 involves selecting or isolating a prober pin 220 to test within the patterned prober pin arrangement 305. Step 630 is applying a first voltage to a contact test point 410 on the prober pin test assembly 408 as detailed above with reference to FIGS. 4B-4D and FIGS. 5A-5D. Step 640 includes sensing a second voltage on a prober pin 220 under test corresponding to the contact test point 410 of the prober pin test assembly 408. Method step 650 includes determining whether or not there is continuity between the contact test point 410 of the prober pin test assembly 408 and the respective prober pin 220_{N} based on the second voltage sensed (e.g. translated through the voltage divider 520) through the input buffer to the controller 404. If the voltage reading recorded at the controller is high (1-5 V), prober pin 220 continuity is determined to be good.

Decision step 660 involves a determination as to whether there a more prober pins 220 in the patterned prober pin arrangement 305 to test. If all prober pins 220 have been tested, the testing is complete. If there are more prober pins 220 to test, the method proceeds to step 620 and another prober pin is selected for testing.

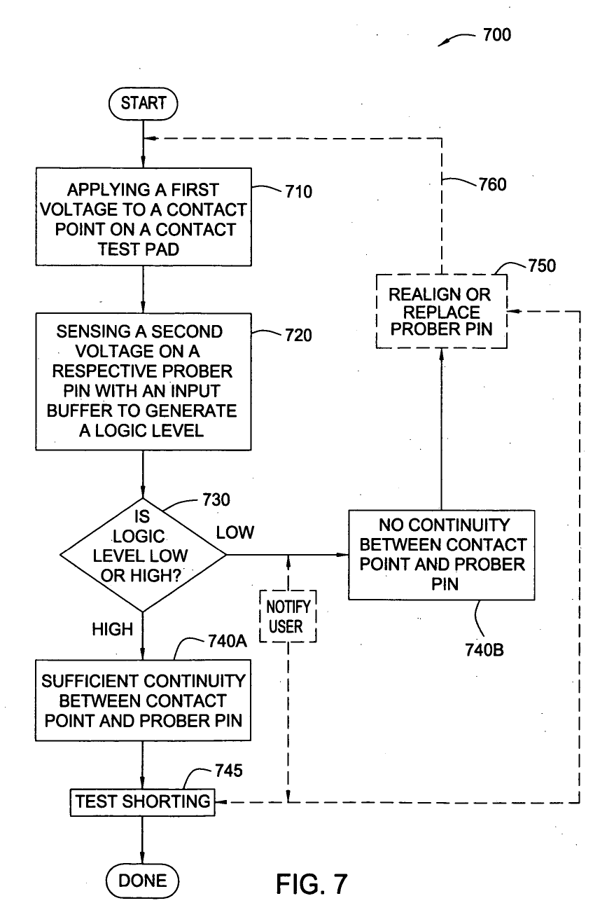

Referring to FIG. 7, logic block 710 summarizes the steps detailed in the description of FIG. 4D and FIGS. 5B-5D of applying the first voltage to a contact point 410_{N} on a contact test pad 405. Block 720 summarizes the steps detailed in the description of FIGS. 5B-5D of sensing a second voltage on a respective prober pin 220_{N} with an input buffer 530 to generate a TTL level on a controller 404. Decision block 730 allows two alternatives determined by the second voltage sensed at the controller 404. If a high voltage, which is defined herein as any voltage equal to or greater than 1, is sensed, the logic steps proceed to block 740A. Block 745 entails sensing of signals or voltages from prober pins 220 that are not under test to discover a shorting pin.

If a low voltage, defined as any voltage less than 1, is sensed from the pin 220 under test, the logic proceeds to block 740B that will confirm a lack of continuity between the contact point 410_{N} and the prober pin 220_{N}. The block 740B may prompt a technician to two possible problems and a method to repair 750. The user may then alternatively realign the suspect prober pin 220_{N} or replace the pin 220_{N} and retest by following line 760. The software employed by the test system may use a windows type program in the controller 404 that will translate a high or low voltage as a “pass” or “no pass” signal. The system may also provide a user notification protocol that will provide text denoting results, problems and possible repair strategies.

While the foregoing is directed to embodiments of the present invention, other and further embodiments of the invention may be devised without departing from the basic scope thereof. The scope of the inventions is determined by the claims that follow.

1. A system for testing continuity of a plurality of prober pins disposed on a prober assembly, the system comprising:
a contact test pad assembly having a plurality of contact points, the contact test pad assembly configured to detachably connect to the plurality of prober pins; and
a controller adapted to provide a first voltage to one of the contact points electrically connected to one of the plurality of prober pins and sense a second voltage from other contact points connected to other prober pins to detect a short between the prober pins.

2. The system of claim 1, further comprising:
a prober pin test circuit connected to the contact test pad assembly and the controller.

3. The system of claim 2, wherein the plurality of contact points are configured to accommodate each of the plurality of prober pins.

4. The system of claim 2, wherein the prober pin test circuit comprises a voltage divider, an input buffer, an open drain driver, a prober pin, a shift register, and a pull-up resistor.

5. The system of claim 1, wherein the contact test pad assembly comprises a frame with at least one alignment device disposed thereon, the frame adapted to detachably connect adjacent the plurality of prober pins by at least one screw in communication with the frame and the prober assembly.

6. The system of claim 3, wherein a ratio of the plurality of contact points to the plurality of prober pins is 2:1 or greater.

7. A prober pin continuity test system for testing the continuity of a plurality of prober pins disposed on a prober, the prober configured to test electronic devices on a large area substrate, the test system comprising:
a contact test pad assembly comprising a plurality of contact points, the contact test pad assembly configured to detachably connect to the plurality of prober pins, and adapted to test electrical continuity of the plurality of prober pins while disposed on the prober;
a controller; and
a prober pin test circuit connected to the contact test pad assembly and the controller, wherein the controller provides a first signal to one of the plurality of contact points electrically connected to a first one of the plurality of prober pins and senses a second signal indicative of continuity from at least a second one of the plurality of prober pins.

8. The system of claim 7, wherein the a plurality of contact points are of a number to accommodate each of the plurality of prober pins.

9. The system of claim 7, wherein the prober pin test circuit comprises a voltage divider, an input buffer, an open drain driver, a prober pin, a shift register, and a pull-up resistor.

10. The system of claim 7, wherein the contact test pad assembly comprises a frame with at least one alignment device disposed thereon, the frame adapted to detachably connect adjacent the plurality of prober pins by at least one screw in communication with the frame and the prober.

11. The system of claim 8, wherein a ratio of the plurality of contact points to the plurality of prober pins is 2:1 or greater.

12. A prober pin continuity test system for testing continuity between one or more prober pins, the prober pins disposed on a prober configured to test electronic devices on a large area substrate, the system comprising:
a plurality of contact test points configured to detachably connect to the plurality of prober pins, the plurality of contact test points adapted to test electrical continuity of the plurality of prober pins;
a controller; and
a prober pin test circuit connected to the plurality of contact test points, the prober pin test circuit comprising:
a shift register to shift a logical signal to a first one of the contact points, wherein the controller senses a second signal from one or more of the plurality of contact points.

13. The system of claim 12, wherein the plurality of contact points are of a number to accommodate each of the plurality of prober pins.

14. The system of claim 12, wherein the contact test pad assembly comprises a frame with at least one alignment device disposed thereon, the frame adapted to detachably connect adjacent the plurality of prober pins by at least one screw in communication with the frame and the adjacent prober bar.

15. The system of claim 12, wherein a ratio of the plurality of contact points to the plurality of prober pins is 2:1 or greater.

16. A method of testing continuity of a prober pin disposed on a prober configured to test electronic devices on a large area substrate, the system comprising:
positioning a prober pin test assembly in communication with the prober, the prober having one or more prober pins disposed thereon;
applying a first voltage to a first contact point on the prober pin test assembly;
sensing a second voltage on a prober pin under test corresponding to the first contact point; and
determining whether or not there is continuity between the contact point and the prober pin under test based on the second voltage.

17. The method of claim 16, wherein the positioning further comprises attaching the prober pin test assembly to a probe head disposed on the prober.

18. The method of claim 16, wherein the applying a first voltage further comprises shifting a logic signal through a shift register.

19. The method of claim 18, wherein the sensing a second voltage further comprises a voltage generated at an input buffer.

20. The method of claim 19, wherein the determining continuity comprises receiving, by a controller, a logical value output from the input buffer.
